(19) United States
(12) Patent Application Publication
(10) Pub. No.: US 2015/0217991 A1
(43) Pub. Date: Aug. 6, 2015

(54) MEMS DEVICE WITH SPLIT PAD PACKAGE

(71) Applicant: InvenSense, Inc., San Jose, CA (US)

(72) Inventors: Anthony D. MINERVINI, Palos Hills, IL (US); Aleksey S. KHENKIN, Nashua, NH (US); Baris CAGDASER, Sunnyvale, CA (US)

(73) Assignee: InvenSense, Inc., San Jose, CA (US)

(21) Appl. No.: 14/170,178

(22) Filed: Jan. 31, 2014

(51) Int. Cl. B81B 7/00

(52) U.S. Cl. CPC B81B 7/007; B81B 2201/0257

(57) ABSTRACT

A device and a microphone are disclosed. The device comprises a circuit board and a plurality of pads on the circuit board, wherein at least one of the plurality of pads is split into at least two portions that are electrically isolated from each other. The microphone comprises a circuit board, a seal structure on the circuit board, and a plurality of pads on the circuit board, wherein at least one of the plurality of pads is split into at least two portions that are electrically isolated from each other.

### FIELD OF THE INVENTION

The present invention relates to microelectromechanical systems (MEMS) devices, and more particularly, to a MEMS device with split pad package.

### BACKGROUND

Microelectromechanical systems (MEMS) devices conventionally exist in packages with multiple contact pins or pads, each such pad serving a single function. In many applications, the total number and/or locations of the pads are restricted by requirements beyond the MEMS device manufacturer's control. These restrictions may limit improvements or enhancements of functions, specifications, and/or other aspects of the device performance when such improvements or enhancements require additional pins or pads. Therefore, there is a need for a solution that overcomes the aforementioned limitations. The present invention addresses such a need.

### SUMMARY OF THE INVENTION

A device and a microphone are disclosed. In a first aspect the device comprises a circuit board and a plurality of pads on the circuit board, wherein at least one of the plurality of pads is split into at least two portions that are electrically isolated from each other.

In a second aspect, the device comprises a circuit board, a seal structure on the circuit board, and a plurality of pads on the circuit board, wherein at least one of the plurality of pads is split into at least two portions that are electrically isolated from each other.

In a third aspect, the microphone comprises a circuit board, a seal structure on the circuit board, and a plurality of pads on the circuit board, wherein at least one of the plurality of pads is split into at least two portions that are electrically isolated from each other.

### BRIEF DESCRIPTION OF THE DRAWINGS

The accompanying figures illustrate several embodiments of the invention and, together with the description, serve to explain the principles of the invention. One of ordinary skill in the art readily recognizes that the embodiments illustrated in the figures are merely exemplary, and are not intended to limit the scope of the present invention.

FIG. 1 illustrates a bottom view of a circuit package in accordance with an embodiment.

FIG. 2 illustrates a view of a customer board in accordance with an embodiment.

FIG. 3 illustrates a mounted device overlaid on a customer board in accordance with an embodiment.

### DETAILED DESCRIPTION

The present invention relates to microelectromechanical systems (MEMS) devices, and more particularly, to a MEMS device with split pad package. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiments shown but is to be accorded the widest scope consistent with the principles and features described herein.

Micro-Electro-Mechanical Systems (MEMS) refers to a class of devices fabricated using semiconductor-like processes and exhibiting mechanical characteristics such as the ability to move or deform. MEMS often, but not always, interact with electrical signals. A MEMS device may refer to a semiconductor device implemented as a microelectromechanical system. A MEMS device includes mechanical elements and optionally includes electronics for sensing or driving. MEMS devices include, but are not limited to, gyroscopes, accelerometers, magnetometers, pressure sensors, and microphones.

In MEMS devices, a port is an opening through a substrate to expose MEMS structure to the surrounding environment. A chip includes at least one substrate typically formed from a semiconductor material. A single chip may be formed from multiple substrates, wherein the substrates are mechanically bonded to preserve functionality. Multiple chip includes at least two substrates, wherein the at least two substrates are electrically connected but do not require mechanical bonding.

MEMS wafers are silicon wafers that contain MEMS structures. MEMS structures may refer to any feature that may be part of a larger MEMS device. One or more MEMS features comprising moveable elements is a MEMS structure. MEMS features may refer to elements formed by a MEMS fabrication process such as bump stop, damping hole, via, port, plate, proof mass, standoff, spring, and seal ring.

MEMS substrates provide mechanical support for the MEMS structure. The MEMS structural layer is attached to the MEMS substrate. The MEMS substrate is also referred to as handle substrate or handle wafer. In some embodiments, the handle substrate serves as a cap to the MEMS structure. Bonding may refer to methods of attaching, and the MEMS substrate and an integrated circuit (IC) substrate may be bonded using a eutectic bond (e.g., AlGe, CuSn, AuSi), fusion bond, compression, thermocompression, adhesive bond (e.g., glue, solder, anodic bonding, glass frit). An IC substrate may refer to a silicon substrate with electrical circuits, typically CMOS circuits. A package provides electrical connection between bond pads on the chip to a metal lead that can be soldered to a printed board circuit (PCB). A package typically comprises a substrate and a cover.

In certain products and devices (e.g., microphone devices, MEMS microphones), the footprint of the device is continuously decreasing while the complexity of the device is staying the same or even increasing in terms of the number of pads necessary. Additionally, the amount of space on the device itself to make electrical contact is decreasing but the physical requirements to make an acoustic seal to that part in the device is staying the same. Therefore, a method and system in accordance with the present invention utilizes a portion of one of the plurality of pads that are used to form the acoustic seal of the device to serve as an I/O pad temporarily during certain parts of the manufacturing and testing of the device.

While the multi-purpose pads can serve a plurality of functions during the manufacturing and testing of the device, all of the multi-purpose pads are shorted to any of a ground, a power, and any other circuit node to create a single pad footprint when the multi-purpose pads are applied to a circuit board by a customer and/or end user. More specifically, splitting the pads into multiple portions creates temporary pads that are used for a variety of functions including but not limited to tuning, trimming, and modifying the functionality of the device during device manufacturing and/or testing. Subsequently, the temporary pads are shorted together to create a single pad so that the device can be used by the customer that does not need the usage of the temporary pads.

A method and system in accordance with the present invention provide a device comprising a circuit board and a plurality of pads on the circuit board. At least one of the plurality of pads is split into at least two portions that are electrically isolated from each other. The two portions serve a first function during the manufacturing and/or testing of the device and serve a second function after the device has been included in a manufactured product and is being used by a customer and/or end user. Once the device has been included in a manufactured product, the two portions can be electrically connected together during the normal operation of the device by the customer and/or end user. The device can be a variety of devices including but not limited to a microphone and a MEMS microphone.

In one embodiment, at least one of a plurality of pads on a circuit board of a device is a power pin that is split into two parts that preserve a general outline. One of the two parts is used for extra functionality during the manufacturing and/or testing of the device and the other of the two parts is used for power functionalities. When a customer and/or end user uses the device, the two parts of the power pin are shorted to create a single power pin or a single pad footprint. In this embodiment, the device benefits from extra functionality during testing, while preserving industry-standard footprints for the customer and/or end user.

In another embodiment, a device includes a circuit board, a seal ring/structure (e.g., an acoustic seal ring) coupled to the circuit board, and a plurality of pads coupled to the circuit board. The acoustic seal ring is redefined such that it maintains an original outer perimeter shape, while having isolated islands located within an annulus of the acoustic seal ring. This allows for additional test points during the manufacturing of the device. The additional test points are shorted to the acoustic seal ring when reflowed to a customer board. Therefore, the acoustic seal ring may either be at an integrated circuit (IC) power supply pin (VDD), or at ground (GND), or at any other circuit node required by the customer, and circuitry for the additional test points accommodates a final condition.

To describe the features of the present invention in more detail, refer now to the following description in conjunction with the accompanying Figures.

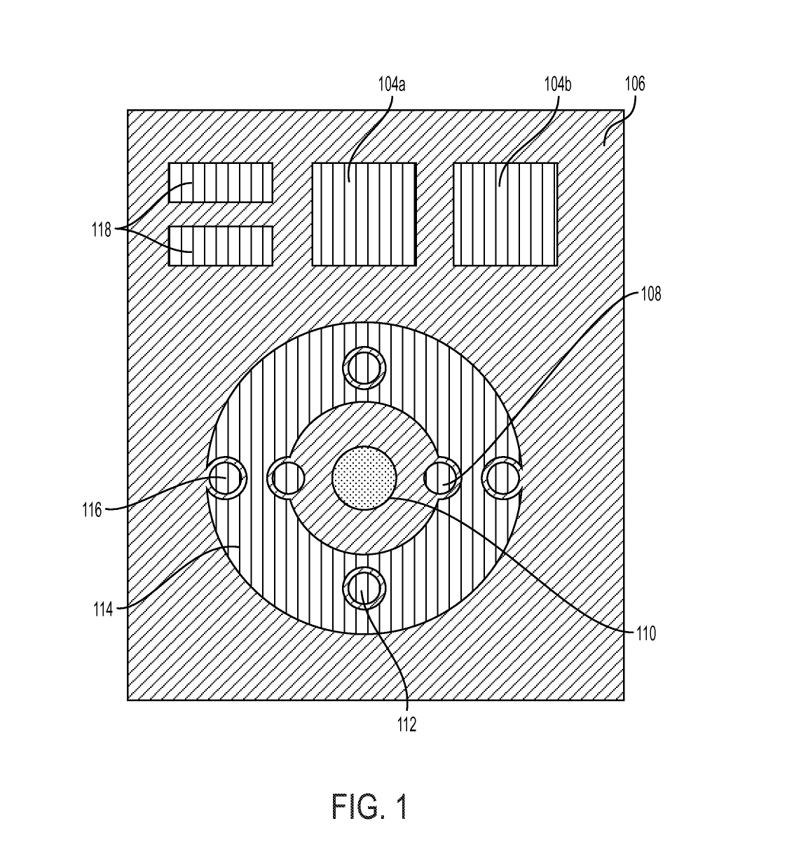

FIG. 1 illustrates a bottom view of a circuit package 100 in accordance with an embodiment. The circuit package 100 includes a split pad 102a and 102b, a plurality of pads 104 and 105, a bottom surface 106 of the circuit package 100, an internal and partially enclosed pad 108, a port 110 on the circuit package 100, an enclosed pad 112, a ring 114, and an external and partially enclosed pad 116. The split pads 102a and 102b are electrically isolated, and therefore can connect to different electrical signals in the microphone and serve different functions. In one embodiment, one of the two split pads is used for extra functionality during manufacturing/testing and the other is used for power supply. In a another embodiment, both the split pad 102a and 102b have the same functions, for example, test pins or power pins. The ring 114 serves as an acoustic seal in addition to being a pad. In FIG. 1, port 110 provides an opening in package 100 to expose the MEMS structure of the MEMS device to the surrounding environment. MEMS devices can be any of an acoustic sensor, pressure sensor, humidity sensor, gas sensor, and any sensor that requires access to the environment.

Enclosed pad 112 is situated inside ring 114 and electrically isolated from ring 114. Internal and partially enclosed pad 108 is situated between the port 110 and ring 114, and in the inner periphery of ring 114. External and partially enclosed pad 116 is situated on the outer periphery of the ring 114 and electrically isolated from ring 114.

The ring 114, enclosed pad 112, internal and partially enclosed pad 108, and external and partially enclosed pad 116 can connect to different signals in the MEMS device and are electrically isolated from each other and the ring 114. The different signals could provide connections to circuits that are used in manufacturing and testing of the MEMS device. Some embodiments may not have all the pads, enclosed pad 112, internal and partially enclosed pad 108, and external and partially enclosed pad 116. Different locations and number of pads are contemplated.

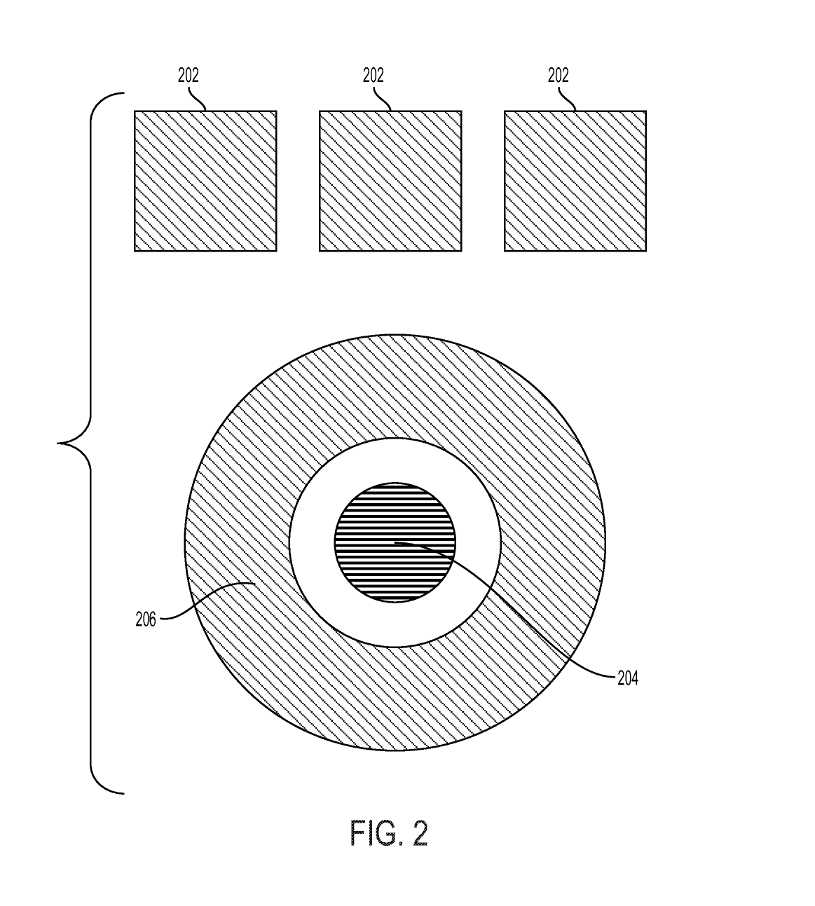

FIG. 2 illustrates a view of a customer board 200 in accordance with an embodiment. The customer board 200 includes pads 202, 204, 205, a port 210, and a seal ring 214. In one embodiment, the pads and the ring of the customer board 200 are aligned with the pads and ring of the circuit package 100 during the manufacture of the customer board 200. In one embodiment, split pads 102a and 102b are connected to pad 202 and pads 104 and 105 are connected to pads 204 and 205 on the customer board 200.

The seal ring 114, enclosed pad 112, internal and partially enclosed pad 108, and external and partially enclosed pad 116 are connected to the seal ring 214 during the manufacture of the customer board 200 thereby electrically connecting the enclosed pad 112, internal and partially enclosed pad 108, and external and partially enclosed pad 116.

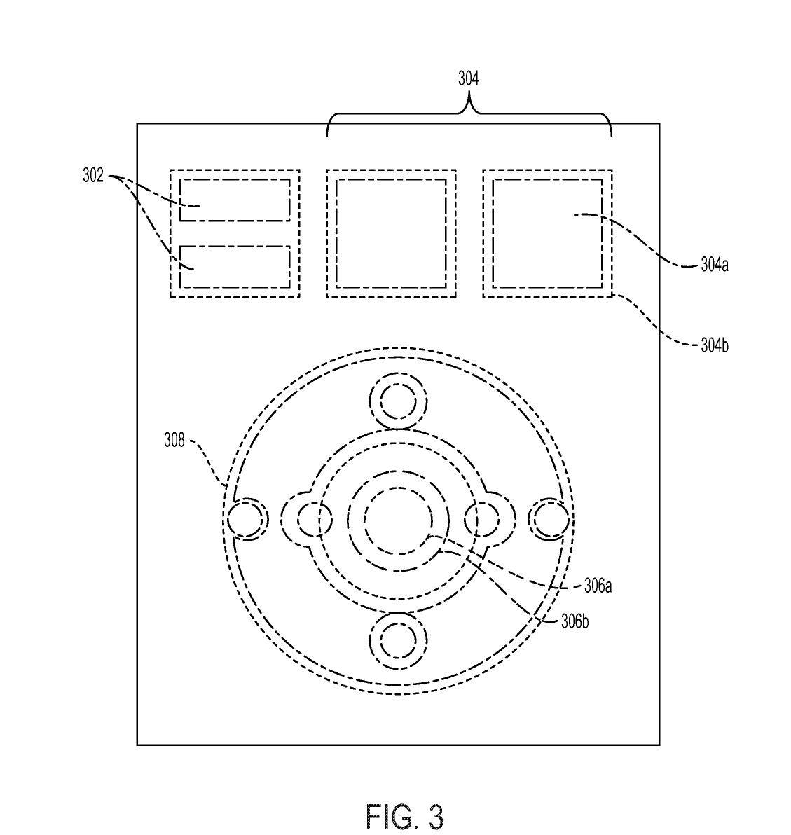

FIG. 3 illustrates a mounted device 300 overlaid on a customer board in accordance with an embodiment. The mounted device 300 includes a split pad 302 that is on a circuit package and that is joined to a single pad of the customer board, a plurality of pads 304, wherein each of the plurality of pads 304 has a package pad 304a and a customer pad 304b, a port comprising a package port 306a and a customer port 306b, and a customer acoustic seal with an annulus 308. The annulus 308 encompasses all package pads, thereby creating an acoustic seal while simultaneously making all package pads within its extent electrically common.

In one embodiment, the mounting (attaching) process consists of using solder to join the pads on the customer board to the pads on the package. In the case of split pads on the package, the split pads become electrically common with each other because they are overlaid with pads on the customer board and joined by solder. The split pad 302 has temporary multi-purpose functionalities that enable each portion to serve a different function (e.g., testing) during the manufacturing and assembly of the mounted device 300. In one embodiment, the temporary multi-purpose functionalities of the split pad 302 are no longer accessible once the split pad 302 has been joined by solder to the customer board during the mounting process.

In one embodiment, a device comprises a circuit board and a plurality of pads on the circuit board, wherein at least one of the plurality of pads is split into at least two portions that are electrically isolated from each other. The at least two portions serve one function during manufacturing and/or testing of the device, and a different function after the device has been included in a manufactured product. In one embodiment, all of the at least two portions are electrically connected together during normal operation of the device by an end user or customer.

In one embodiment, the plurality of pads comprises any of a power pad and a ground pad. In one embodiment, during manufacturing and/or testing of the device, one of the at least two portions provides test functionality and the other of the at least two portions provides power functionality.

In one embodiment, a device comprises a circuit board, a seal structure on the circuit board, and a plurality of pads on the circuit board, wherein at least one of the plurality of pads is split into at least two portions that are electrically isolated from each other. The at least two portions serve one function during manufacturing and/or testing of the device, and a different function after the device has been included in a manufactured product. In one embodiment, all of the at least two portions are electrically connected together during normal operation of the device by an end user or customer.

In one embodiment, the device further comprises a chip connected to at least one of the plurality of pads. In one embodiment, the chip is any of a sensor, a microphone, a pressure sensor, and a humidity sensor. In one embodiment, the seal structure is any of a circular shape, oval shape, rectangular shape, and a square shape. In one embodiment, the at least one of the plurality of pads is within the seal structure and is electrically isolated from the seal structure. In another embodiment, the at least one of the plurality of pads is any of nested and partially nested within the seal structure and is electrically isolated from the seal structure.

In one embodiment, a microphone comprises a circuit board, a seal structure on the circuit board, and a plurality of pads on the circuit board, wherein at least one of the plurality of pads is split into at least two portions that are electrically isolated from each other. The at least two portions serve one function during manufacturing and/or testing of the device, and a different function after the device has been included in the microphone. In one embodiment, all of the at least two portions are electrically connected together during normal operation of the device by an end user or customer.

In one embodiment, the plurality of pads comprises any of a power pad and a ground pad. In one embodiment, during manufacturing and/or testing of the device, one of the at least two portions provides test functionality and the other of the at least two portions provides power functionality.

In one embodiment, the microphone further comprises a chip connected to at least one of the plurality of pads. In one embodiment, the chip is any of a sensor, a microphone, a pressure sensor, and a humidity sensor. In one embodiment, the seal structure is any of a circular shape, oval shape, rectangular shape, and a square shape. In one embodiment, the at least one of the plurality of pads is within the seal structure and is electrically isolated from the seal structure. In another embodiment, the at least one of the plurality of pads is partially within the seal structure and is electrically isolated from the seal structure.

As above described, a method and system in accordance with the present invention uses split pads on an integrated circuit package to enable greater functionality and satisfy acoustic seal requirements, while saving space and minimizing space requirements of a device or manufactured product. By splitting the pads into multiple portions, the pads can serve a plurality of functions at various durations of the life cycle of the device, while still maintaining similar size and spacing to non-split padded devices. Therefore, the split pads retain standard landing pad and solder mask recommendations so the customer printed circuit board (PCB) is not affected, and the industry-standard footprint is retained. The split pad design enables customization of various parts (e.g., package) of the device without affecting the overall implementation.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A device comprising:
a circuit board; and
a plurality of pads on the circuit board, wherein at least one of the plurality of pads is split into at least two portions that are electrically isolated from each other.

2. The device of claim 1, wherein the at least two portions serve one function during manufacturing of the device and a different function after the device has been included in a manufactured product.

3. The device of claim 1, wherein all of the at least two portions are electrically connected together during normal operation of the device.

4. The device of claim 1, wherein the at least one of the plurality of pads comprises any of a power pad and a ground pad.

5. The device of claim 1, wherein during manufacturing, one of the at least two portions provides test functionality and the other of the at least two portions provides power.

6. The device of claim 2, wherein the one function is a test function.

7. A device comprising:
a circuit board;
a seal structure on the circuit board;
a plurality of pads on the circuit board, wherein at least one of the plurality of pads is split into at least two portions that are electrically isolated from each other.

8. The device of claim 7, wherein the at least two portions serve one function during manufacturing of the device and a different function after the device has been included in a manufactured product.

9. The device of claim 7, wherein all of the at least two portions are electrically connected together during normal operation of the device.

10. The device of claim 7, further comprising:
a chip connected to at least one of the plurality of pads.

11. The device of claim 7, wherein the chip is a sensor.

12. The device of claim 11, wherein the sensor is a microphone.

13. The device of claim 11, wherein the sensor is any of a pressure sensor and a humidity sensor.

14. The device of claim 7, wherein the seal structure is any of circular, oval, rectangular, and square.

15. The device of claim 7, wherein the at least one of the plurality of pads is within the seal structure and is electrically isolated from the seal structure.

16. The device of claim 7, wherein the at least one of the plurality of pads is nested within the seal structure and is electrically isolated from the seal structure.

17. The device of claim 7, wherein the at least one of the plurality of pads is partially nested within the seal structure and is electrically isolated from the seal structure.

18. A microphone comprising:
a circuit board;
a seal structure on the circuit board; and
a plurality of pads on the circuit board, wherein at least one of the plurality of pads is split into at least two portions that are electrically isolated from each other.

19. The microphone of claim 18, wherein the at least two portions serve one function during manufacturing of the device and a different function after the device has been included in a manufactured product.

20. The microphone of claim 18, wherein all of the at least two portions are electrically connected together during normal operation of the device.

21. The microphone of claim 18, wherein the at least one of the plurality of pads comprises any of a power pad and a ground pad.

22. The microphone of claim 18, wherein during manufacturing, one of the at least two portions provides test functionality and the other of the at least two portions provides power.

23. The microphone of claim 18, further comprising:
a chip connected to at least one of the plurality of pads.

24. The microphone of claim 23, wherein the chip is a sensor.

25. The microphone of claim 24, wherein the sensor is a microphone.

26. The microphone of claim 24, wherein the sensor is any of a pressure sensor and a humidity sensor.

27. The microphone of claim 18, wherein the seal structure is any of circular, oval, rectangular, and square.

28. The microphone of claim 18, wherein the at least one of the plurality of pads is within the seal structure and is electrically isolated from the seal structure.

29. The microphone of claim 18, wherein the at least one of the plurality of pads is partially within the seal structure and is electrically isolated from the seal structure.
